(19) United States
(12) Patent Application Publication
(10) Pub. No.: US 2007/0035202 A1
(43) Pub. Date: Feb. 15, 2007

(54) Piezoelectric actuator, lens driving device, and image taking device

(75) Inventor: Ryo Imai, Asaka (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/483,011

(22) Filed: Jul. 10, 2006

(30) Foreign Application Priority Data
Jul. 29, 2005 (JP) 2005-220214

(51) Int. Cl. H01L 41/00

(52) U.S. Cl. 310/311; 600/437

(57) ABSTRACT

A piezoelectric actuator includes a deformable section including a piezoelectric member that deforms when subjected to a voltage and an electrode that is in contact with the piezoelectric member, and a buffer section consisting of a substance that absorbs an impact, the buffer section being in contact with at least a part of the piezoelectric member.

### BACKGROUND OF THE INVENTION

1. Field of the Invention

The present invention relates to a piezoelectric actuator deformed when subjected to a voltage, a lens driving device that drives a lens, and an image taking device that takes an image of a subject.

2. Description of the Related Art

In recent years, image taking devices that take images of subjects have been commonly built into small-sized instruments such as cellular phones. When a small-sized instrument carried by a user includes an image taking device, the user can easily take images at any time without the need to carry a digital camera or video camera with him or her. These small-sized instruments commonly provide a data communication function using radio or ultraviolet rays and can advantageously send a taken image instantly to another cellular phone or a personal computer.

However, image taking devices built into small-sized instruments such as cellular phones are much smaller than ordinary digital cameras and are thus severely limited in the sizes of a lens, a CCD (Charge Coupled Device), and the like as well as a space in which the lens, CCD, and the like are housed. Thus, the image taking functions of these small-sized instruments, the quality of images taken with them, and the like are insufficient when they are used in place of digital cameras. Their applications are thus often limited to image taking that does not require high image quality; they are often used to take an image instead of taking note or to take an image for a standby screen for a cellular phone or the like.

Under these circumstances, high pixel-count, small-sized CCDs and corresponding small-sized lenses, and the like have recently been developed. The quality of images taken using small-sized instruments has thus been rapidly improved. To solve the remaining problem, that is, to improve the image taking function, these small-sized instruments are desirably equipped with an auto focus function or a zoom function normally provided in digital cameras.

The auto focus function and zoom function are generally provided by using rotation of a motor to move the lens along an optical axis via a cam mechanism. However, a large motor. mounted in an image taking device significantly increases the size and weight of the entire image taking device. Sufficient power to drive the lens motor is required in addition to power required to carry out a normal image taking function. It is therefore difficult to install the auto focus function or zoom function using a motor, in a cellular phone or the like, the size and weight of which has been desired to be reduced.

In connection with this, Japanese Patent Laid-Open Nos. 2004-294759 and 2004-294580 describe image taking devices that use a piezoelectric actuator instead of a motor to move a lens. The piezoelectric actuator is composed of a piezoelectric element such as a piezoelectric ceramic plate which is characterized by being deformed in response to an applied voltage. The piezoelectric actuator can thus be driven with reduced space and power compared to the above motor. The piezoelectric element is also characterized by generating a counter electromotive force when deformed. Japanese Patent Laid-Open No. 2002-315362 describes a technique for reusing a counter electromotive force as a driving force for the piezoelectric actuator. Application of these techniques enables even a small-sized image taking device built into a cellular phone or the like to reliably move the lens. This makes it possible to provide the auto focus function or zoom function.

Small-sized instruments such as cellular phones often fail to be gripped and fall from users' hands. Since the piezoelectric actuator is formed of a thin plate-like piezoelectric ceramic, it is disadvantageously easily broken when subjected to an impact. Thus, when the piezoelectric actuator is applied to a small-sized image taking device, the impact of a fall may damage the piezoelectric actuator, making the lens unable to move. In some cases, broken pieces scattering in the image taking device may break the device itself to prevent image taking of subjects.

These problems are not limited to image taking devices but may occur in any applications using piezoelectric actuators.

### SUMMARY OF THE INVENTION

The present invention has been made in view of the above circumstances and provides a piezoelectric actuator, a lens driving device, and an image taking device which are unlikely to be damaged even if they are subjected to an impact such as of a fall.

The present invention provides a piezoelectric actuator including:

a deformable section which has a piezoelectric member that deforms when subjected to a voltage and an electrode that is in contact with the piezoelectric member, and

a buffer section consisting of a substance that absorbs an impact, the buffer section being in contact with at least a part of the piezoelectric member.

The piezoelectric member is commonly composed of a piezoelectric ceramic plate or the like and is easily broken when subjected to an impact such as of a fall. Even when an impact is made on the piezoelectric actuator in accordance with the present invention, it is absorbed by the buffer material that is in contact with the piezoelectric member to reduce damage to the piezoelectric member.

In the piezoelectric actuator in accordance with the present invention, the buffer section is preferably a tube surrounding the piezoelectric member.

The piezoelectric member is surrounded by the tube to reliably absorb an impact applied to the piezoelectric member.

In the piezoelectric actuator in accordance with the present invention, the buffer section is also preferably a lamellar member adhering to a surface of the piezoelectric member.

Damage to the piezoelectric member is also efficiently avoided by the adhesion of the lamellar member to the surface of the piezoelectric member; the lamellar member is composed of a substance which absorbs impacts.

In the piezoelectric actuator in accordance with the present invention, it is suitable that the deformable section is a hollow piezoelectric Helimorph extending in spiral form, and the buffer section is a bar-like member fitted into the spiral form.

The bar-like member fitted into the spiral form of the deformable section suppresses an increase in the size of the piezoelectric Helimorph. This makes it possible to avoid damage to the piezoelectric Helimorph.

The present invention provides a lens driving device including:

a lens which holds section that holds a lens;

a movement guide that guides movement of the lens in a predetermined direction;

a deformable section which has an piezoelectric member that deforms when subjected to a voltage and an electrode that is in contact with the piezoelectric member, the deformable section coming into contact with the lens holding section to transmit deformation stress to the lens holding section to move the lens; and

a buffer section consisting of a substance that absorbs an impact, the buffer section being in contact with at least a part of the piezoelectric member.

The lens driving device in accordance with the present invention enables the lens to be driven with reduced spaces and power and also reduces possible damage to the piezoelectric member caused by an impact such as of a fall.

The present invention provides an image taking device including:

a lens holding section that holds a lens;

a movement guide that guides movement of the lens in a predetermined direction;

a deformable section which has a piezoelectric member that deforms when subjected to a voltage and an electrode that is in contact with the piezoelectric member, the deformable section coming into contact with the lens holding section to transmit deformation stress to the lens holding section to move the lens;

a buffer section consisting of a substance that absorbs an impact, the buffer section being in contact with at least a part of the piezoelectric member; and

an image taking section that takes an image of a subject light having passed through the lens.

The present invention provides a small-sized, power-saving image taking device which is unlikely to be damaged.

The present invention provides a piezoelectric actuator, a lens driving device, and an image taking device which are unlikely to be damaged even if they are subjected to an impact such as of a fall.

### BRIEF DESCRIPTION OF THE DRAWINGS

FIG. 1 is a diagram illustrating the operational principle of a piezoelectric Bimorph that is a kind of a piezoelectric actuator;

FIG. 2 is a diagram showing a first method for forming a buffer section in a basic piezoelectric actuator and a buffer piezoelectric actuator that is a first embodiment of the present invention;

FIG. 3 is a diagram showing a second method for forming a buffer section in a basic piezoelectric actuator and a buffer piezoelectric actuator that is a second embodiment of the present invention;

FIG. 4 is a diagram showing a third method for forming a buffer section in the basic piezoelectric actuator and a buffer piezoelectric actuator that is a third embodiment of the present invention;

FIG. 5 is a diagram showing a fourth method for forming a buffer section in the basic piezoelectric actuator and a buffer piezoelectric actuator that is a fourth embodiment of the present invention;

FIG. 6 is a diagram showing a fifth method for forming a buffer section in the basic piezoelectric actuator and a buffer piezoelectric actuator that is a fifth embodiment of the present invention;

FIG. 7 is a perspective view showing the appearance of digital camera in accordance with an embodiment of the present invention as viewed obliquely from above the front surface of the digital camera;

FIG. 8 is a schematic block diagram of the digital camera 100 shown in FIG. 7; and

FIG. 9 is a perspective view of the digital camera 100 in which an image taking lens and a lens driving section are arranged, as viewed obliquely from the front surface of the digital camera.

### DETAILED DESCRIPTION OF THE INVENTION

Embodiments of the present invention will be described with reference to the drawings.

First, the operational principle of piezoelectric actuators will be described.

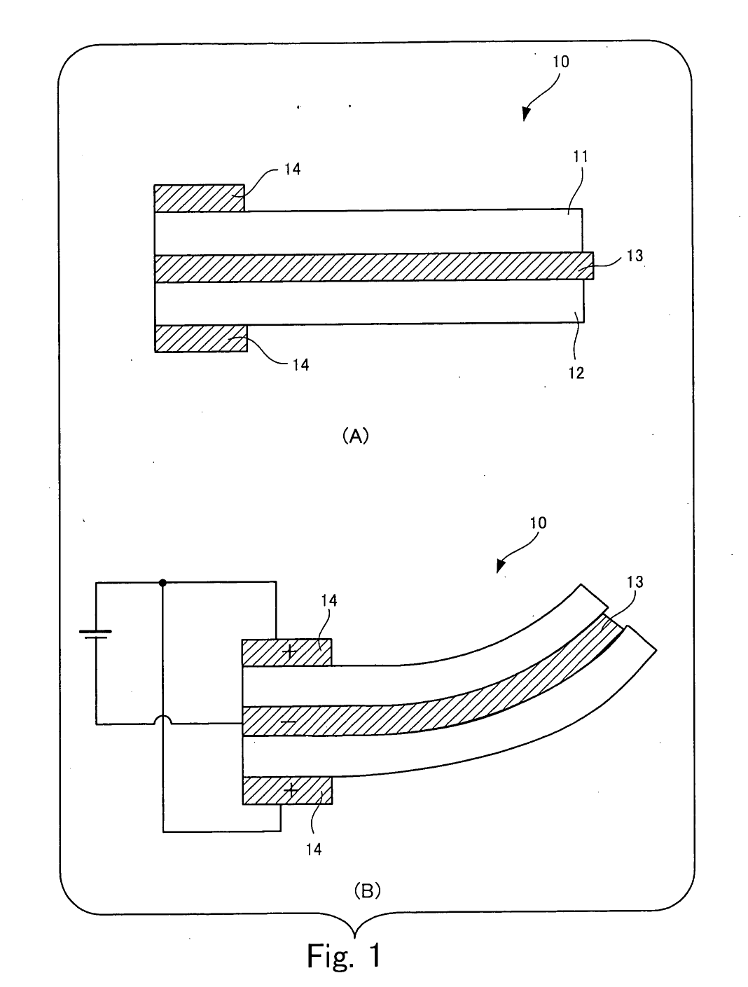

FIG. 1 illustrates the operational principle of a piezoelectric Bimorph that is a kind of piezoelectric actuator.

A piezoelectric Bimorph 10 has an electrode 13 sandwiched between two piezoelectric plates 11 and 12 polarized across the thickness in the same direction. The piezoelectric Bimorph 10 also has counter electrodes 14 for the electrode 13 provided on each of the piezoelectric plates 11 and 12. Piezoelectric ceramics plates are used as the piezoelectric plates 11 and 12. Metal plates such as gold electrodes are used as the electrode 13 and counter electrodes 14. The piezoelectric plates 11 and 12 are examples of piezoelectric members in accordance with the present invention. The electrode 13 and counter electrodes 14 are examples of electrodes in accordance with the present invention. The piezoelectric Bimorph 10 is an example of a deformable section in accordance with the present invention.

Part (A) of FIG. 1 shows that with no voltage applied to the piezoelectric Bimorph 10, the two piezoelectric plates 11 and 12 are in an equal expansion state and the piezoelectric Bimorph 10 remains straight.

When voltages of opposite polarities are applied to the electrode 13 and each counter electrode 14, one of the piezoelectric elements (in Part (B) of FIG. 1, the upper piezoelectric element 11) is contracted as a result of a piezoelectric horizontal effect, while the other piezoelectric element (in Part (B) of FIG. 1, the lower piezoelectric element 12) is expanded. This causes the piezoelectric Bimorph 10 to be bent upward. When voltages of polarities opposite to those shown in Part (B) of FIG. 1 are applied to the electrode 13 and each counter electrode 14, the piezoelectric Bimorph 10 is bent downward, that is, in the direction opposite to that shown in Part (B) of FIG. 1.

The piezoelectric Bimorph 10 is deformed on the basis of the principle described above. Explanation will be given of the operational principle of a piezoelectric Bimorph formed of two plate-like piezoelectric members. However, basically similar principles apply to deformation of, for example, a piezoelectric Unimorph formed of a single plate-like piezoelectric member and a piezoelectric Helimorph with a hollow, spirally twisted piezoelectric member. The description of these operational principles is thus omitted.

The piezoelectric plates 11 and 12, shown in FIG. 1, are composed of hard piezoelectric ceramics and are disadvantageously liable to be damaged by an impact such as of a fall. In the piezoelectric actuator in accordance with the present invention, a buffer section composed of an elastic material absorbs an impact applied to the piezoelectric member. This avoids damaging the piezoelectric member. In the description below, a piezoelectric actuator in which a buffer section has been formed is called a buffer piezoelectric actuator. The piezoelectric actuator in which the buffer section has not been formed yet is called a basic piezoelectric actuator. A detailed description will be given below of a method of forming a buffer section in the basic piezoelectric actuator and the buffer piezoelectric actuator in which the buffer section has been formed.

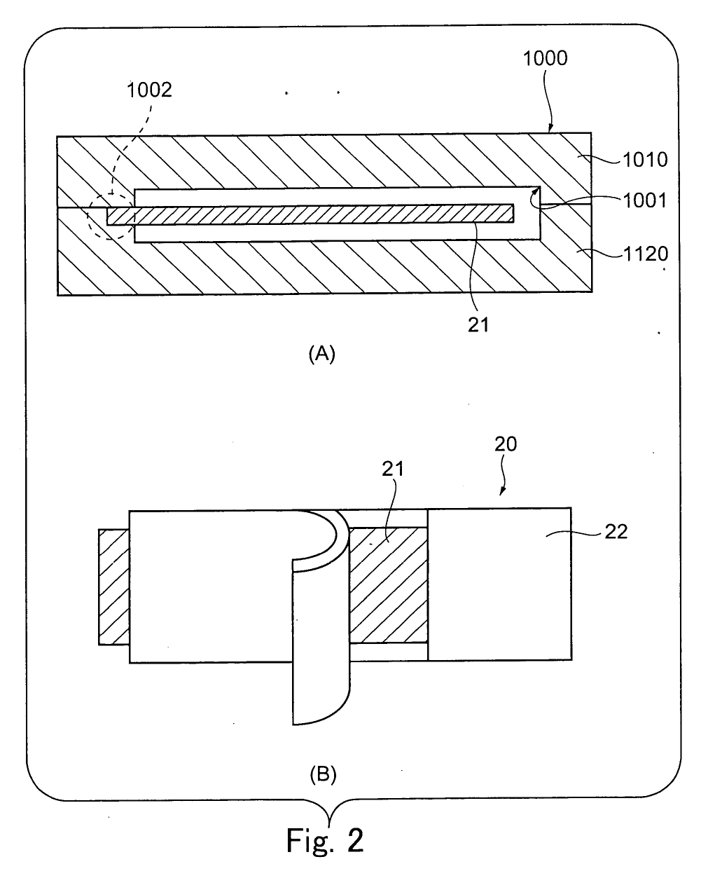

FIG. 2 shows a first method of forming a buffer section in the basic piezoelectric actuator and a buffer piezoelectric actuator 20 that is a first embodiment of the present invention.

Part (A) of FIG. 2 shows a molding apparatus 1000 composed of an upper mold 1010 and a lower mold 1020 that are fitted together. A fixation section 1002 and an injection space 1001 are formed between the upper mold 1010 and the lower mold 1020; a basic piezoelectric actuator 21 is fixed to the fixation section 1002 and a fluidic elastic material is injected into the injection space 1001.

First, the basic piezoelectric actuator 21 configured similarly to the piezoelectric Bimorph 10, shown in FIG. 1, is fixed to the fixation section 1002. A fluidic elastic material is subsequently injected into the injection space 1001. Rubber or urethane is used as an elastic material. Once the elastic material is solidified, the upper mold 1010 and lower mold 1020 are removed.

Part (B) of FIG. 2 is a partial sectional view of the buffer piezoelectric actuator 20 to which the elasticmaterial has been attached by the molding apparatus 1000, shown in Part (A) of FIG. 2. The buffer piezoelectric actuator 20 is composed of the basic piezoelectric actuator 21 and a lamellar buffer section 22 composed of an elastic material and covering the entire outer surface of the basic piezoelectric actuator 21. The basic piezoelectric actuator 21 is an example of a deformable section in accordance with the present invention. The buffer section 22 is an example of a lamellar member and a buffer section in accordance with the present invention.

When an impact such as of a fall is made on the buffer piezoelectric actuator 20, it is absorbed by the buffer section 22, which covers the basic piezoelectric actuator 21. This reliably avoids possible damage to the basic piezoelectric actuator 21.

The first embodiment in accordance with the present invention has been described. A second embodiment in accordance with the present invention will be described below. The basic piezoelectric actuator, in which the buffer section has not been formed, has different shapes between the first and second embodiments.

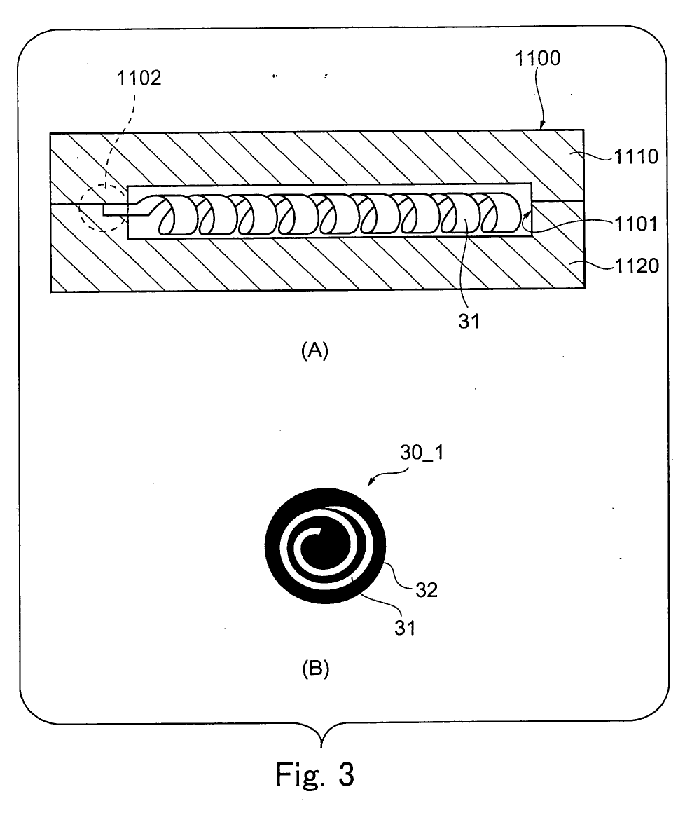

FIG. 3 shows a second method of forming a buffer section in the basic piezoelectric actuator and a buffer piezoelectric actuator 30_1 that is the second embodiment of the present invention.

Like Part (A) of FIG. 2, Part (A) of FIG. 3 shows a molding apparatus 1100 composed of an upper mold 1110 and a lower mold 1120. In the present embodiment, a basic piezoelectric actuator 31 is fixed to a fixation section 1102; a basic piezoelectric actuator 31 is composed of a piezoelectric member extending in a hollow, spiral form. An elastic material is injected into an injection space 1101. The basic piezoelectric actuator 31 is an example of a deformable section and a piezoelectric Helimorph in accordance with the present invention.

Part (B) of FIG. 3 is a sectional view of the buffer piezoelectric actuator 30_1 to which the elastic material has been attached by the molding apparatus 1100, shown in Part (A) of FIG. 3; the sectional view is taken along a plane perpendicular to the center axis of the spiral form. The buffer piezoelectric actuator 30_1 is composed of the basic piezoelectric actuator 31 fitted into a solid, cylindrical buffer section 32. In other words, in the basic piezoelectric actuator 31, the elastic material is filled into the spiral form and the entire outer surface of the spiral form is covered with the elastic material.

The basic piezoelectric actuator 31 is prone to be bent because it is shaped like a long, hollow spiral. However, the entire surface of the basic piezoelectric actuator 31 is in contact with the buffer section 32, which is also filled into the spiral form. This allows a possible impact applied to the buffer piezoelectric actuator 30_1 to be reliably absorbed.

The second embodiment in accordance with the present invention has been described. A third embodiment in accordance with the present invention will be described below. The second and third embodiments use the same basic piezoelectric actuator, in which the buffer section has not been formed, except for a method for forming a buffer section and the form of the buffer section.

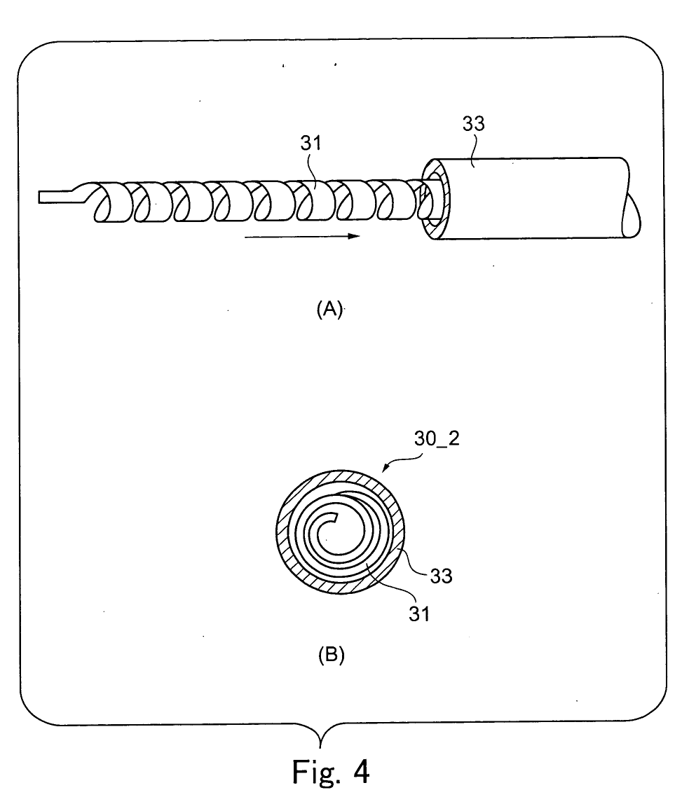

FIG. 4 shows a third method of forming a buffer section in the basic piezoelectric actuator and a buffer piezoelectric actuator 30_2 that is the third embodiment of the present invention.

Part (A) of FIG. 4 shows a tube 33 composed of an elastic material and the basic piezoelectric actuator 31, which is shaped like a long, hollow spiral similarly to that in the second embodiment, shown in FIG. 3. The present embodiment inserts the basic piezoelectric actuator 31 into the tube 33.

Part (B) of FIG. 4 is a sectional view of a buffer piezoelectric actuator 30_2 composed of the tube 33, into which the basic piezoelectric actuator 31 is inserted; the sectional view is taken along a plane perpendicular to the center axis of the spiral of the basic piezoelectric actuator 31. The basic piezoelectric actuator 31 has a spiral outer surface surrounded by the tube 33. The tube 33 is an example of a tube and a buffer section in accordance with the present invention.

By thus inserting the basic piezoelectric actuator 31 into the tube 33, it is possible to easily manufacture an impact-resistant buffer piezoelectric actuator 30_2.

The third embodiment in accordance with the present invention has been described. A fourth embodiment in accordance with the present invention will be described below. The fourth embodiment of the present invention uses the same basic piezoelectric actuator, in which the buffer section has not been formed, as that in the second and third embodiments except for a method for forming a buffer section and the form of the buffer section.

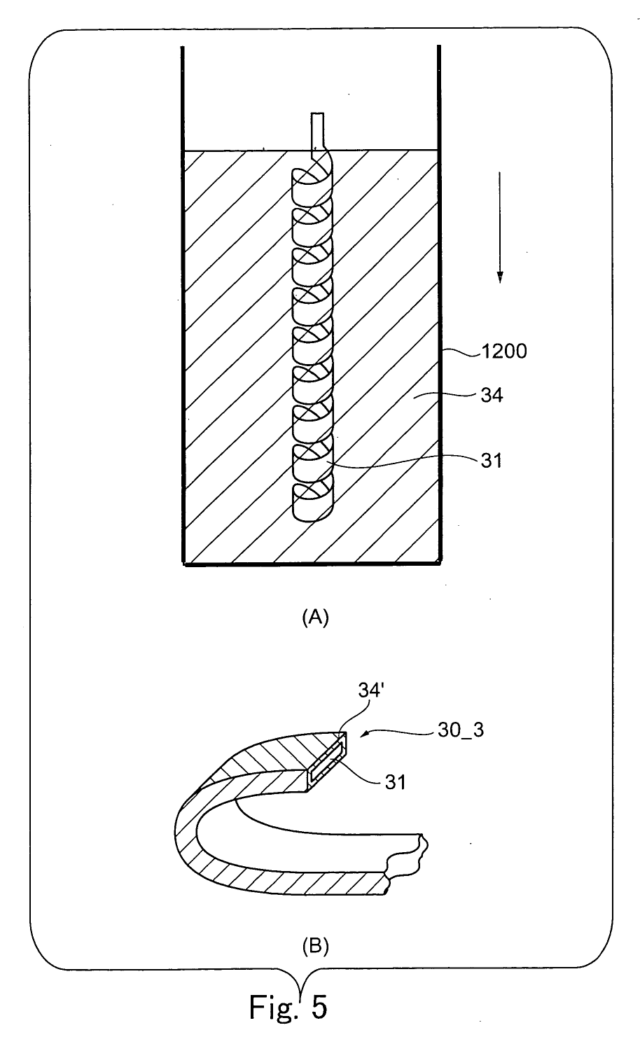

FIG. 5 shows a fourth method of forming a buffer section in the basic piezoelectric actuator and a buffer piezoelectric actuator 30_3 that is the fourth embodiment of the present invention.

Part (A) of FIG. 5 shows a container 1200 in which a fluidic elastic material 34 is accommodated and the basic piezoelectric actuator 31 that is a piezoelectric Helimorph similarly to the second and third embodiments, shown in FIGS. 3 and 4, respectively. Immediately after being inserted into the container 1200 in which the elastic material 34 is accommodated, the basic piezoelectric actuator 31 is pulled out. Outside the container 1200, the elastic material 34 coated on the basic piezoelectric actuator 31 is solidified.

Part (B) of FIG. 5 shows the buffer piezoelectric actuator 30_3 formed by solidifying the elastic material 34; the sectional view is taken along a plane crossing the spiral of the basic piezoelectric actuator 31. The buffer piezoelectric actuator 30_3 has buffer sections 34′ each formed on the outer surface of the corresponding spiral piece of the basic piezoelectric actuator 31 by attaching the elastic material 34 to the outer surface. The buffer section 34′ is also an example of a lamellar member and a buffer portion in accordance with the present invention.

By thus forming buffer portions 34′ only on the surface of the basic piezoelectric actuator 31, it is possible to improve the impact resistance of the buffer piezoelectric actuator 30_3 using a reduced amount of elastic material.

The fourth embodiment in accordance with the present invention has been described. A fifth embodiment in accordance with the present invention will be described below. The fifth embodiment of the present invention uses the same basic piezoelectric actuator as that in the second, third, and fourth embodiments except for a method for forming a buffer section and the form of the buffer section.

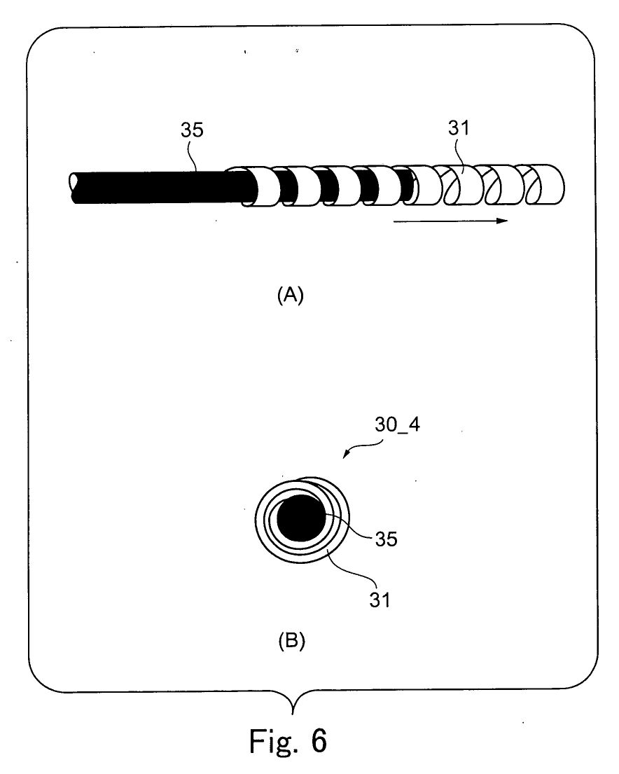

FIG. 6 shows a fifth method of forming a buffer section in the basic piezoelectric actuator and a buffer piezoelectric actuator 30_4 that is the fifth embodiment of the present invention.

Part (A) of FIG. 6 shows a bar-like elastic material 35 and the basic piezoelectric actuator 31 that is a piezoelectric Helimorph similarly to those of the second, third, and fourth embodiments, shown in FIGS. 3, 4, and 5, respectively. The present embodiment inserts the elastic material 35 into the spiral form of the basic piezoelectric actuator 31.

Part (B) of FIG. 6 shows the buffer piezoelectric actuator 30_4 into which the bar-like elastic material 35 has been inserted; the sectional view is taken along a plane perpendicular to the center axis of spiral of the basic piezoelectric actuator 31. In the buffer piezoelectric actuator 30_4, the outer peripheral surface of the basic piezoelectric actuator 31 is not covered with the elastic material 35, which is instead fitted into the basic piezoelectric actuator 31. The elastic material 35 is an example of a bar-like member and a buffer section in accordance with the present invention.

By thus fitting the bar-like elastic material into the spiral form of the basic piezoelectric actuator 31, it is possible to improve the impact resistance of the buffer piezoelectric actuator 30_4, while avoiding an increase in the size of the buffer piezoelectric actuator 30_4.

Description has been given of the methods for forming a buffer section in the basic piezoelectric actuator and the buffer piezoelectric actuators in which the buffer section is formed. Description will be given below of examples of applications of the piezoelectric actuator in accordance with the present invention. Additionally, description will be given of an example in which the piezoelectric actuator in accordance with the present invention is mounted in a digital camera to move a lens.

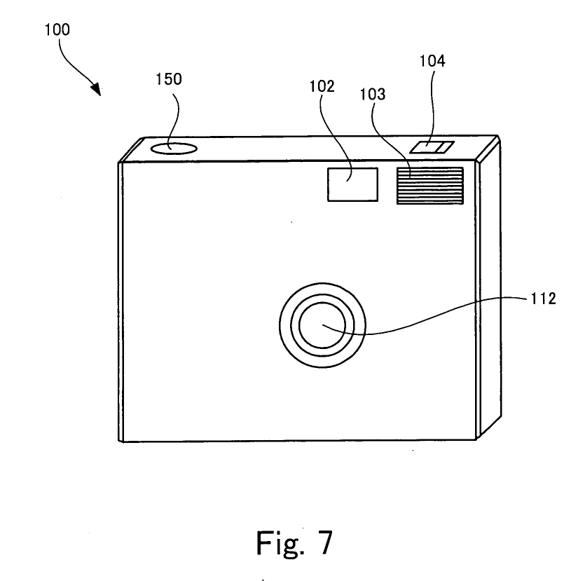

FIG. 7 is a perspective view showing the appearance of a digital camera that is an embodiment of an image taking device in accordance with the present invention as viewed from obliquely above the front surface of the digital camera.

As shown in FIG. 7, the digital camera 100 has an image taking lens 112, an optical finder objective window 102, and a flash emitting section 103 on its front surface. The digital camera 100 has a sliding power switch 104 and a release switch 150 on its top surface.

Although not shown in FIG. 7, the following are provided on a side and back surfaces of the digital camera 100: an image display section that displays images, a loading port through which print media is loaded, a zoom switch that switches an operation between telescopic image taking and wide-angle image taking, and an image taking mode switch that switches between an image taking mode and a playback mode.

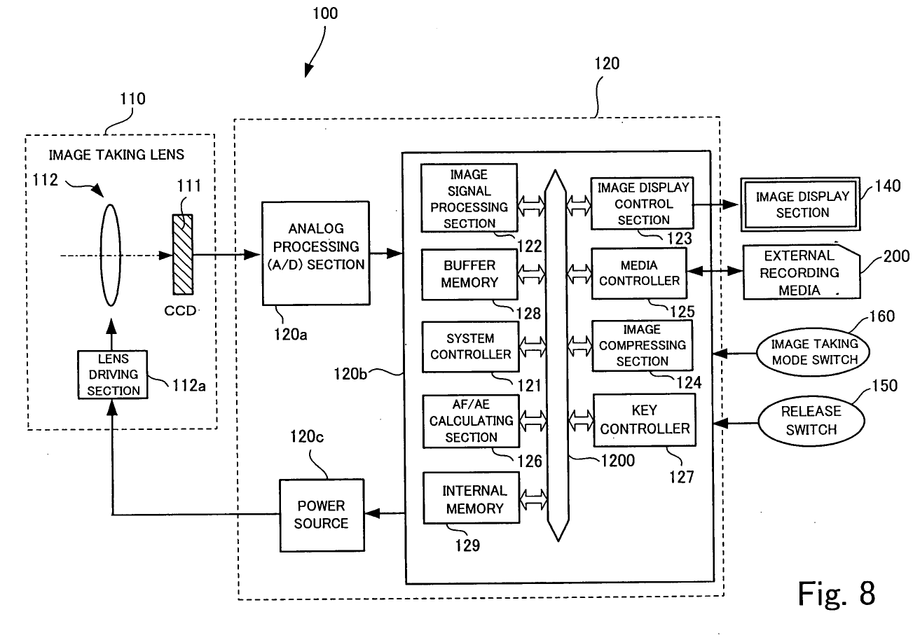

FIG. 8 is a schematic block diagram showing the digital camera 100, shown in FIG. 7.

As shown in FIG. 8, the digital camera 100 has an image taking optical system 110 and a signal processing section 120. The digital camera 100 also has an image display section 140 that displays taken images, external recording media 200 in which taken image signals are recorded, an image taking mode switch 160 that allows the digital camera 100 to execute various processes for image taking, and a release switch 150.

First, the configuration of the image taking optical system 100 will be described with reference to FIG. 8.

The digital camera 100 forms an image of light from a subject on a CCD 111 through the image taking lens 112.

A lens driving section 112a includes a buffer piezoelectric Helimorph 30_3 having a lamellar buffer section 34′ on the entire surface of the basic piezoelectric Helimorph 31 shown in FIG. 5. In accordance with an instruction from a system controller 121 in the signal processing section 120, a voltage from a power source 120c is applied to the buffer piezoelectric Helimorph 30_3, which is then deformed in response to the applied voltage. The image taking lens 112 is thus driven along the optical axis. The present embodiment also provides a TTLAF (Through The Lens Auto Focus) function. Specifically, while the lens driving section 112a is moving the image taking lens 112 within a predetermined driving range, an AF/AE calculating section 126 of the signal processing section 120 detects the contrast of image signals repeatedly obtained by the CCD 111. The image taking lens 112 is then adjusted to a lens position at which the peak of the contrast is obtained. The TTLAF function enables an image taking operation to be performed with the camera automatically focused on a subject so as to obtain the peak contrast.

The subject light having passed through the image taking lens 112 is formed into an image on the CCD 111, which thus generates an image signal representing a subject image. The CCD 111 is an example of an image taking section in accordance with the present invention.

The image taking optical system 110 is configured as described above.

Subsequently, the configuration of the signal processing section 120 will be described.

The subject image formed on the CCD 111 is read and loaded into an analog processing (A/D) section 120a as an image signal. The analog processing (A/D) section 120a converts the analog signal into a digital signal, which is then supplied to a digital signal processing section 120b. A system controller 121 is provided in the digital signal processing section 120b. Instructions from the system controller 121 control processes executed by various elements shown in FIG. 8. Delivery of data is carried out via a bus 1200 among the system controller 121, an image signal processing section 122, an image display control section 123, an image compressing section 124, a media controller 125, the AF/AE calculating section 126, a key controller 127, and a buffer memory 128. An internal memory 129 operates as a buffer when data is delivered via the bus 1200. Data containing variables for the progresses of processes in the respective sections is written to the internal memory 129 at any time. With reference to this data, appropriate processes are executed by the system controller 121, image signal processing section 122, image display control section 123, image compressing section 124, media controller 125, AF/AE calculating section 126, and key controller 127. Instructions from the system controller 121 are transmitted to the above sections via the bus 1200 to start up the process in each section. The data in the internal memory 129 is rewritten according to the progresses of the processes. The system controller 121 further refers to the rewritten data to manage the operation of each section. In other words, the power supply is turned on to start up the process in each section in accordance with the procedures of programs in the system controller 121. For example, when the release switch 150 or image taking mode switch 160 is operated, information indicating the operation is transmitted to the system controller 121 via the key controller 127. A process corresponding to the operation is then executed in accordance with the procedure of the corresponding program in the system controller 121.

A release operation causes image data read from the CCD 111 to be converted from an analog signal to a digital signal by an analog processing (A/D) section 120a. The digitalized image data is then stored in the buffer memory 128 in the digital signal processing section 120b. An RGB signal for the digitalized image data is converted into a YC signal by the image signal processing section 122. The YC signal is further subjected to a compression called JPEG compression by the image compressing section 124. The image signal is thus recorded in the external recording media 200 via the media controller 125 as an image file. The image data recorded as an image file is reproduced by the image display section 140 through the image display control section 123. During this process, the AF/AE calculating section 126 detects, for focusing, the contrast for each distance to the subject on the basis of the RGB signal. On the basis of the detection, focusing is carried out using a focus lens in the image taking lens 112. The AF/AE calculating section 126 extracts a luminance signal from the RGB signal to detect a depth of field.

The digital camera 100 is basically configured as described above.

The lens driving section 112a will subsequently be described in detail.

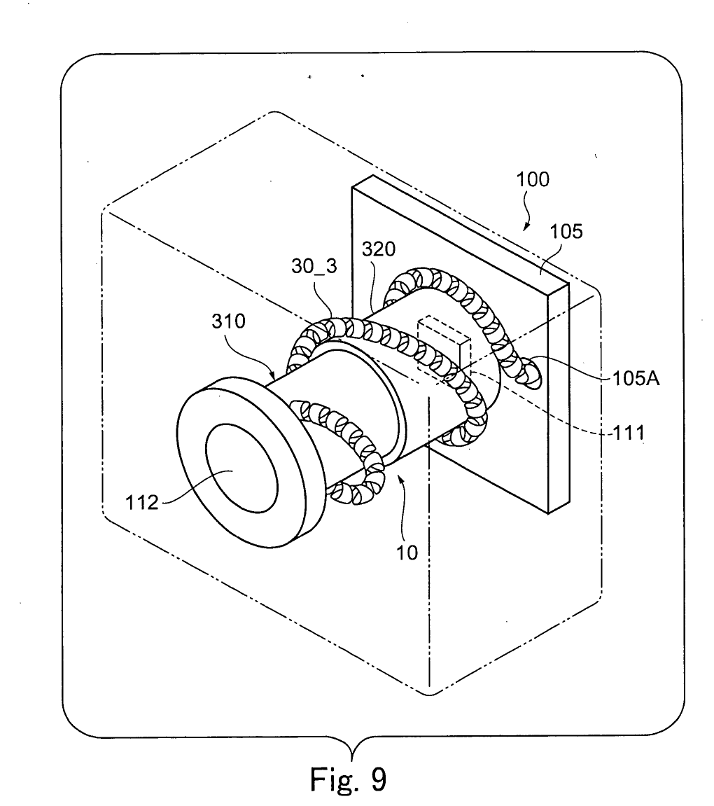

FIG. 9 is a perspective view of the digital camera 100 in which the image taking lens 112 and lens driving section 112a are arranged, as viewed from the front surface of the digital camera 100.

The lens driving section 112a is composed of a lens barrel 310 that holds the image taking lens 112, the buffer piezoelectric actuator 30_3 also shown in FIG. 5, a guide cylinder 320 supporting the lens barrel 310, and a voltage applying section (not shown) connected to a power source 120c (see FIG. 8) to apply a voltage to the buffer piezoelectric actuator 30_3. The lens barrel 310 is an example of a lens holding section in accordance with the present invention. The guide cylinder 320 is an example of a movement guide in accordance with the present invention.

The guide cylinder 320 projects from the CCD holding section 105, fixed to a main body housing of the digital camera 100. The lens barrel 310 is fitted into the cylindrical form so as to be movable in a front-to-back direction. The buffer piezoelectric actuator 30_3 extends in a longitudinal direction with one end fixed to the front end of the lens barrel 310. The buffer piezoelectric actuator 30_3 is wound around the outer surface of the lens barrel 310. The other end of the buffer piezoelectric actuator 30_3 passes through a through-hole 105A in the CCD holding section 105 and is connected to the voltage applying section in rear of the CCD holding section 105.

In accordance with an instruction from the system controller 121, shown in FIG. 8, the voltage applying section (not shown) applies a voltage of a predetermined polarity and a predetermined value to the buffer piezoelectric actuator 30_3. In response to the applied voltage, the buffer piezoelectric actuator 30_3 is deformed so as to reduce its own front-to-back length over which it is wound around the outer surface of the lens barrel 310. At this time, the buffer piezoelectric actuator 30_3 pulls the lens barrel 310 rearward along the guide cylinder 320. Application of a voltage of the opposite polarity to the buffer piezoelectric actuator 30_3 increases the front-to-back length of the actuator 30_3 over which it is wound around the outer surface of the lens barrel 310. The buffer piezoelectric actuator 30_3 thus pushes the lens barrel 310 forward along the guide cylinder 320. Thus, the adjustment of the voltage applied to the buffer piezoelectric actuator 30_3 controls the expansion and contraction of the buffer piezoelectric actuator 30_3. The image taking lens 112 is thus moved to an arbitrary lens position to execute an AF function or a zoom function.

As described above, the size of the entire digital camera 100 can be reduced by allowing the buffer piezoelectric actuator 30_3 to move the lens 112 without using any motor. The small-sized digital camera 100 often fails to be gripped and falls from the user's hand. However, the buffer piezoelectric actuator 30_3 is unlikely to be damaged in spite of an impact such as of a fall because the impact is absorbed by the buffer section 34′ shown in FIG. 5. Thus, the digital camera 100 in accordance with the present embodiment is unlikely to be damaged in spite of an impact such as of a fall and enables stable image taking operations.

In the description of the above examples, the piezoelectric actuator in accordance with the present invention is applied to the digital camera. However, the piezoelectric actuator in accordance with the present invention may be used in applications other than digital cameras.

In the above description, the buffer section in accordance with the present invention is in contact with both a piezoelectric member and an electrode. However, the buffer section in accordance with the present invention may be in contact only with, for example, the piezoelectric member.

What is claimed is:

1. A piezoelectric actuator comprising:
a deformable section including a piezoelectric member that deforms when subjected to a voltage and an electrode that is in contact with the piezoelectric member; and
a buffer section consisting of a substance that absorbs an impact, the buffer section being in contact with at least a part of the piezoelectric member.

2. The piezoelectric actuator according to claim 1, wherein the buffer section is a tube surrounding the piezoelectric member.

3. The piezoelectric actuator according to claim 1, wherein the buffer section is a lamellar member adhering to a surface of the piezoelectric member.

4. The piezoelectric actuator according to claim 1, wherein the deformable section is a hollow piezoelectric Helimorph extending in spiral form; and
the buffer section is a bar-like member fitted into the spiral form.

5. A lens driving device comprising:
a lens holding section that holds a lens;
a movement guide that guides movement of the lens in a predetermined direction;
a deformable section including a piezoelectric member that deforms when subjected to a voltage and an electrode that is in contact with the piezoelectric member, the deformable section coming into contact with the lens holding section to transmit deformation stress to the lens holding section to move the lens; and
a buffer section consisting of a substance that absorbs an impact, the buffer section being in contact with at least a part of the piezoelectric member.

6. An image taking device comprising:
a lens holding section that holds a lens;
a movement guide that guides movement of the lens in a predetermined direction;
a deformable section including a piezoelectric member that deforms when subjected to a voltage and an electrode that is in contact with the piezoelectric member, the deformable section coming into contact with the lens holding section to transmit deformation stress to the lens holding section to move the lens;
a buffer section consisting of a substance that absorbs an impact, the buffer section being in contact with at least a part of the piezoelectric member; and
an image taking section that takes an image of a subject light having passed through the lens.
